(19) United States
(12) Patent Application Publication
(10) Pub. No.: US 2025/0140519 A1
(43) Pub. Date: May 1, 2025

(54) METHOD OF ADJUSTING CHARGED PARTICLE BEAM WRITING APPARATUS, CHARGED PARTICLE BEAM WRITING APPARATUS AND COMPUTER-READABLE RECORDING MEDIUM

(71) Applicant: NuFlare Technology, Inc., Yokohama-shi (JP)

(72) Inventors: Michihiko IKEDA, Yokohama-shi (JP); Akinori MINE, Yokohama-shi (JP); Koji URUSHIZAKI, Yokohama-shi (JP); Wataru KUNISHIMA, Yokohama-shi (JP); Tomoyuki HORIUCHI, Yokohama-shi (JP)

(73) Assignee: NuFlare Technology, Inc., Yokohama-shi (JP)

(21) Appl. No.: 18/911,476

(22) Filed: Oct. 10, 2024

(30) Foreign Application Priority Data
Oct. 25, 2023 (JP) 2023-183367

(51) Int. Cl. H01J 37/304; H01J 37/20

(52) U.S. Cl. CPC H01J 37/304; H01J 37/20

(57) ABSTRACT

In one embodiment, a method of adjusting charged particle beam writing apparatus includes transporting a substrate before writing received via an interface from an outside to a writing chamber and placing the substrate on a stage, irradiating the substrate on the stage with a charged particle beam to write a pattern, and transporting the substrate after writing from the writing chamber to the outside via the interface. At least part of adjustment work for devices in the charged particle beam writing apparatus is performed during transport of the substrate between the interface and the writing chamber.

### CROSS REFERENCE TO RELATED APPLICATION

This application is based upon and claims benefit of priority from the Japanese Patent Application No. 2023-183367, filed on Oct. 25, 2023, the entire contents of which are incorporated herein by reference.

### FIELD

The present invention relates to a method of adjusting charged particle beam writing apparatus, a charged particle beam writing apparatus and a computer-readable recording medium.

### BACKGROUND

As LSI circuits are increasing in density, the required linewidths of circuits included in semiconductor devices become finer year by year. To form a desired circuit pattern on a semiconductor device, a method is employed in which a high-precision original pattern (i.e., a mask, or also particularly called reticle, which is used in a stepper or a scanner) formed on quartz is transferred to a wafer in a reduced manner by using a reduced-projection exposure apparatus. The high-precision original pattern is written by using an electron-beam writing apparatus, in which a so-called electron-beam lithography technique is employed.

In an electron beam writing apparatus, writing is performed while deflecting an electron beam by a deflector. A DAC (digital analog convertor) amplifier unit is used to deflect an electron beam. The function of beam deflection using the DAC amplifier unit includes control of the shape and size of a beam shot, control of the shot position, and blanking of the beam. In recent years, in order to further miniaturize the pattern of a reticle, the accuracy (such as resolution, error, and noise) required for the output of the DAC amplifier unit has been increased.

The characteristics of the components constituting the DAC amplifier unit slowly vary in time, which affects the output accuracy of the DAC amplifier unit, and may cause an error in the written pattern. For this reason, the operation of the DAC amplifier unit is diagnosed and adjusted to maintain the output accuracy. Gain adjustment and linearity correction are known as the diagnosis and adjustment of the DAC amplifier unit.

The diagnosis and adjustment of the DAC amplifier unit are performed in regular maintenance of the writing apparatus. Thus, there is a problem in that the regular maintenance takes time, and the downtime of the writing apparatus increases, causing reduction in the productivity.

When the maintenance is cut down, for example, the frequency of the regular maintenance is reduced to decrease the downtime of the writing apparatus, the product may be produced without detecting a problem of the writing apparatus, such as reduction in the output accuracy of the DAC amplifier unit, which may cause quality deterioration of the product.

### BRIEF DESCRIPTION OF THE DRAWINGS

FIG. 1 is a plan view of an electron beam writing apparatus according to an embodiment of the present invention.

FIG. 2 is a partial sectional view of the electron beam writing apparatus according to the embodiment.

FIG. 3 is a table illustrating an example of an order of adjustment works to be performed during transport of a substrate.

### DETAILED DESCRIPTION

In one embodiment, a method of adjusting charged particle beam writing apparatus includes transporting a substrate before writing received via an interface from an outside to a writing chamber and placing the substrate on a stage, irradiating the substrate on the stage with a charged particle beam to write a pattern, and transporting the substrate after writing from the writing chamber to the outside via the interface. At least part of adjustment work for devices in the charged particle beam writing apparatus is performed during transport of the substrate between the interface and the writing chamber.

Hereinafter, an embodiment of the present invention will be described based on the drawings. In the present embodiment, a configuration using an electron beam as an example of a charged particle beam will be described. The charged particle beam is not limited to the electron beam. For example, the charged particle beam may be an ion beam.

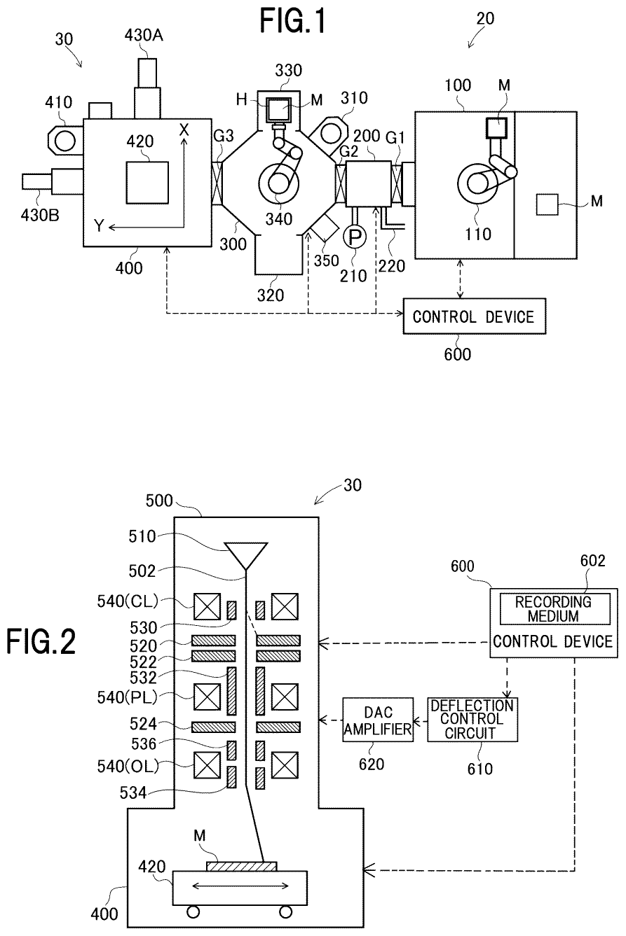

FIG. 1 is a plan view of an electron beam writing apparatus according to an embodiment of the present invention, and FIG. 2 is a sectional view of a writing chamber (W chamber) 400 and an electron beam column 500 which are part of the electron beam writing apparatus. As illustrated in FIG. 1, FIG. 2, the electron beam writing apparatus includes an interface (I/F) 100, a carry-in/out (I/O) chamber 200, a robot chamber (R chamber) 300, a W chamber 400, an electron beam column 500, a control device 600, and gate valves G1 to G3. In FIG. 1, illustration of the electron beam column 500 is omitted.

The I/F 100 has a transport robot (transport arm) 110 for transporting a substrate M as a writing target, and receives the substrate M from the outside of the electron beam writing apparatus, and transports the substrate M to the chamber in the subsequent stage. In addition, the I/F 100 transports the substrate M after writing to the outside of the electron beam writing apparatus.

The substrate M as a writing target includes an exposure mask when a semiconductor device is manufactured, and a semiconductor substrate (silicon wafer) on which a semiconductor device is fabricated. The substrate M may be a mask blank coated with resist and nothing has been written thereon.

The I/O chamber 200 is so-called a load-lock chamber to carry in/out the substrate M with the inside of the R chamber 300 maintained at vacuum (low pressure). The I/O chamber 200 includes a vacuum pump 210 and a gas supply system 220, and the gate valve G1 is provided between the I/F 100 and the I/O chamber 200. The vacuum pump 210 is e.g., a dry pump or a turbo molecular pump, and draws a vacuum in the I/O chamber 200. To achieve atmospheric pressure in the I/O chamber 200, the gas supply system 220 supplies a vent gas (e.g., nitrogen gas and CDA) into the I/O chamber 200.

The vacuum pump 210 connected to the I/O chamber 200 is used to evacuate the inside of the I/O chamber 200. When atmospheric pressure is resumed in the I/O chamber 200, a vent gas is supplied from the gas supply system 220 to achieve atmospheric pressure in the I/O chamber 200. Note that the gate valves G1, G2 are set Close (closed) when the I/O chamber 200 is evacuated and when atmospheric pressure is achieved.

The R chamber 300 includes a vacuum pump 310, an alignment chamber 320, a mask cover housing chamber 330, a transport robot 340, and a soaking chamber 350. The R chamber 300 is coupled to the I/O chamber 200 via the gate valve G2.

The vacuum pump 310 is e.g., a cryopump or a turbo molecular pump. The vacuum pump 310 is connected to the R chamber 300, and draws a vacuum in the R chamber 300 to maintain a high vacuum therein. The alignment chamber 320 is a chamber for positioning (aligning) the substrate M.

The mask cover housing chamber 330 is a chamber for housing mask cover H and placing the mask cover H on the substrate M. The mask cover H is a conductive frame-shaped body having an opening in the center and provided with a plurality of ground mechanisms (pins for grounding). The size of the frame body is slightly larger than that of the substrate M. The mask cover H is for discharging the electric charge accumulated in the substrate M due to irradiation of an electron beam.

The soaking chamber 350 is a chamber for performing a soaking process of adjusting the temperature of the substrate M to the temperature in the ambient environment.

The transport robot 340 transports the substrate M between the I/O chamber 200, the alignment chamber 320, the mask cover housing chamber 330, the soaking chamber 350 and the W chamber 400.

The W chamber 400 includes a vacuum pump 410, an XY stage 420, and drive mechanisms 430A, 430B, and is coupled to the R chamber 300 via the gate valve G3.

The vacuum pump 410 is e.g., a cryopump or a turbo molecular pump. The vacuum pump 410 is connected to the W chamber 400, and draws a vacuum in the W chamber 400 to maintain a high vacuum therein. The XY stage 420 is a stage to place the substrate M thereon. The drive mechanism 430A drives the XY stage 420 in X-direction. The drive mechanism 430B drives the XY stage 420 in Y-direction. The movement of the XY stage 420 is controlled by the control device 600.

As illustrated in FIG. 2, the electron beam column 500 includes an electron beam illumination unit, and irradiates the substrate M placed on the XY stage 420 with an electron beam, the electron beam illumination unit including an electron gun 510, a blanking aperture 520, a first aperture 522, a second aperture 524, a blanking deflector 530, a shaping deflector 532, a main deflector 534, a sub-deflector 536, and a lens 540 (an illumination lens (CL), a projection lens (PL), an objective lens (OL)). Although mask cover H is set to the substrate M to be irradiated with an electron beam, illustration of the mask cover H is omitted in FIG. 2.

An electron beam 502, which is an example of a charged particle beam emitted from the electron gun 510, illuminates the entire first aperture 522 having a rectangular, e.g., square hole by the illumination lens CL. An electron beam 200 is first shaped into a rectangle, e.g., a square. The electron beam of a first aperture image which has passed through the first aperture 522 is projected onto the second aperture 524 by the projection lens PL. The position of the first aperture image on the second aperture 524 is controlled by the shaping deflector 532, and the beam shape and dimensions can be changed. The electron beam of a second aperture image which has passed through the second aperture 524 is focused by the objective lens OL, and deflected by the main deflector 534 and the sub-deflector 536, and radiated to a desired position of the substrate M on the moving XY stage 420. The electron beam writing apparatus is a variable shape writing apparatus.

In beam ON state, the electron beam 502 emitted from the electron gun 510 is controlled by the blanking deflector 530 so as to pass through the blanking aperture 520, and in beam OFF state, the entire beams are deflected so as to be blocked by the blanking aperture 520. One shot of electron beam is given by the electron beam which has passed through the blanking aperture 520 since beam ON state after beam OFF state until the subsequent beam OFF state is achieved. The irradiation amount per shot of the electron beam emitted to the substrate M is adjusted by the irradiation time of each shot.

The control device 600 is e.g., a computer, and has a function of controlling each chamber and each gate valve. In addition, the control device 600 controls the deflection voltages applied to the blanking deflector 530, the shaping deflector 532, the main deflector 534, and the sub-deflector 536.

For example, the control device 600 generates shot data indicating the irradiation time, shot shape, and irradiation position of each shot, and outputs the shot data to a deflection control circuit 610. The deflection control circuit 610 calculates deflection amount data for beam deflection, and outputs the deflection amount data to a DAC amplifier 620. The DAC amplifier 620 converts the deflection amount data as a digital signal into an analog signal, then amplifies the analog signal, and applies the analog signal to each deflector as a deflection voltage. Although only one DAC amplifier 620 is illustrated in FIG. 2, each of the shaping deflector 532, the main deflector 534, and the sub-deflector 536 is provided with a DAC amplifier connected to the corresponding deflector.

Adjustment works need to be regularly performed on the DAC amplifier 620 to maintain the output accuracy. In the adjustment works, for example, the DAC amplifier unit is instructed to output test data, an output value is measured, a parameter to be corrected is calculated from the measurement value, and gain adjustment, linearity correction and the like to finely adjust the reference voltage of the DAC amplifier are performed using the parameter. The adjustment work for the DAC amplifier 620 is performed under the control of the control device 600.

Conventionally, the adjustment work for the DAC amplifier 620 is practiced at the time of regular maintenance of the writing apparatus. For example, the regular maintenance is performed every six months, in which the adjustment work for the DAC amplifier 620 and the maintenance of other hardware are practiced, and the writing apparatus is shut down for about two days, for example. In other words, a downtime of two days occurs every six months.

To cope with this, in the present embodiment, the adjustment work for the DAC amplifier 620 are practiced during transport of the substrate M, at least part of the adjustment works for the DAC amplifier 620 is omitted from the works to be practiced in the regular maintenance so that the workload of the regular maintenance is reduced. Consequently, it is possible to shorten the working hours of the regular maintenance, reduce the downtime of the writing apparatus, and improve the productivity. For example, a downtime of two days in a conventional regular maintenance can be reduced to one day.

Here, during transport of the substrate M refers to transport of the substrate M before writing since it is received from the outside of the electron beam writing apparatus by the I/F 100 until the substrate M is placed on the XY stage 420 of the W chamber 400. In addition, during transport of the substrate M refers to the time other than the writing process period since the substrate M before writing is received from the outside of the electron beam writing apparatus by the I/F 100 until the substrate M after writing is transported to the outside of the electron beam writing apparatus.

In addition, during transport of the substrate M may include not only the time when the substrate M is moved (physically not stopped) by the transport robot 110 or the transport robot 340, but also the time when a soaking process, such as adjustment to a vacuum and adjustment to a temperature, is performed, and the substrate M is physically stopped.

Each deflector is provided with a DAC amplifier. The main deflector 534 and the sub-deflector 536 have a plurality of electrodes, and each electrode is connected to a DAC amplifier. The order of DAC amplifiers for which adjustment works are performed is determined according to times allocatable to the adjustment works for the DAC amplifiers during transport of the substrate M.

For example, a case is assumed in which eight DAC amplifiers (MAMP1 to MAMP8) corresponding to the main deflector 534 are provided, and eight DAC amplifiers (SAMP1 to SAMP8) corresponding to the sub-deflector 536 are provided.

For example, when the adjustment work for one DAC amplifier can be performed during one-time transport of (one piece of) the substrate M, if the substrate M is transported 16 times (16 pieces of the substrate is transported), the adjustment works for the above-mentioned 16 DAC amplifiers (MAMP1 to MAMP8 and SAMP1 to SAMP8) are completed.

When the time allocated to the adjustment works for the DAC amplifiers during transport of the substrate M is shorter than the time taken for the adjustment work for one DAC amplifier, the adjustment work for one DAC amplifier is divided, and performed over the multiple times of transport of the substrate M (transport of multiple pieces of substrate).

Table 1 illustrates an example of times taken for adjustment (gain adjustment and linearity correction) per amplifier of the DAC amplifiers (MAMP1 to MAMP8) corresponding to the main deflector 534, and the DAC amplifiers (SAMP1 to SAMP8) corresponding to the sub-deflector 536.

TABLE 1

Required time

| | Gain adjustment | Linearity correction |
|---|---|---|
| MAMP1~8 | 1 minute | 4 minutes |
| SAMP1~8 | 5 minutes | 10 minutes |

When the time allocatable to the adjustment works for the DAC amplifiers during transport of the substrate M is five minutes, since the total time for the gain adjustment and the linearity correction is five minutes for each of MAMP1 to MAMP8, the adjustment work for one MAMP is completed during one-time transport.

Meanwhile, since the total time for the gain adjustment and the linearity correction is 15 minutes for each of SAMP1 to SAMP8, the adjustment work is divided, and practiced. For example, the adjustment work is divided into gain adjustment, linearity correction (1), and linearity correction (2) and practiced so that each required time is five minutes. Thus, the adjustment work for one SAMP is completed during three times of substrate transport.

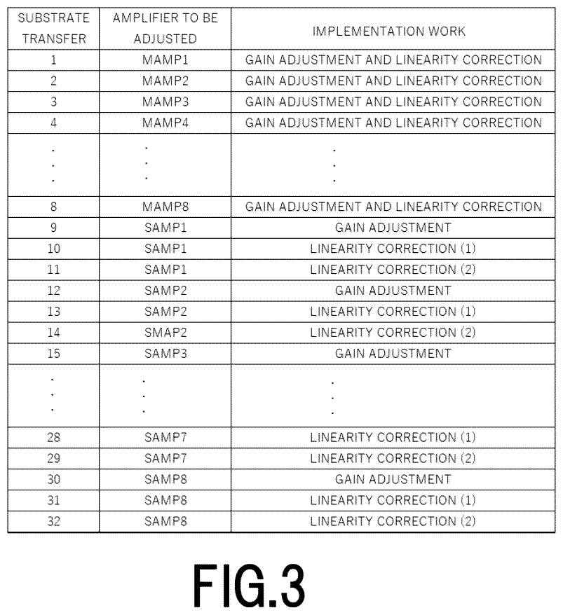

For example, the adjustment works for MAMP1 to MAMP8 and SAMP1 to SAMP8 are divided into the substrate transfer for 32 times (=1×8+3×8) and performed as illustrated in FIG. 3.

The adjustment work to be performed during transport of the substrate M is not limited to the adjustment work for a DAC amplifier, and may be the adjustment work for another device included in the writing apparatus. For example, parameter adjustment, such as transport adjustment of the stage, can be performed. Multiple types of adjustment work may be performed during one-time transport of (one piece of) the substrate M. In this case, it is preferable that execution timing of each work be determined based on the attribute of each adjustment work so that the required time is minimum.

For example, the attribute includes information, such as the time taken for work, concurrent workability with substrate transport, practice place, and an execution order. The “concurrent workability with substrate transport” is an item indicating whether work can be practiced while the substrate is actually being moved by a transport robot. For example, when the substrate is actually being moved by a transport robot, vibration diagnosis cannot be practiced, thus concurrent workability is set “No”.

The “practice place” indicates the place where the substrate M is located when the adjustment work is performed. For example, in the case of adjustment work practiced when the substrate M is stored in the soaking chamber 350, the practice place is set to “soaking chamber”. When the adjustment work can be practiced for the substrate M located at any place between the I/F 100 and the W chamber 400, the practice place is set to “no requirement”.

When there is an order to be executed among multiple adjustment works, an order is set to the “execution order”.

Attribute information on the multiple adjustment works is prepared in advance, and stored in a storage (not illustrated) of the control device 600. The control device 600 refers to the attribute information, and determines the execution timing of each adjustment work.

For example, when the substrate transfer from the I/F 100 to the W chamber 400 includes the processes as in Table 2, and four types of adjustments 1 to 4 are made during transport, the control device 600 refers to the attribute information as in Table 3, and determines the execution timing of each adjustment work so that the required time is minimum.

TABLE 2

| | Time |
|---|---|
| Movement from I/F to I/O chamber | 10 minutes |
| Movement from I/O chamber to soaking chamber | 5 minutes |
| Soaking in soaking chamber | 40 minutes |
| Movement from soaking chamber to alignment chamber | 5 minutes |
| Movement from alignment chamber to W chamber | 5 minutes |

TABLE 3

| | Time taken | Concurrent | Practice | Execution |
|---|---|---|---|---|
| | for work | workability | place | order |
| Adjustment 1 | 10 minutes | Yes | No requirement | No requirement |
| Adjustment 2 | 20 minutes | Yes | No requirement | No requirement |
| Adjustment 3 | 30 minutes | No | Soaking chamber | No requirement |
| Adjustment 4 | 15 minutes | Yes | No requirement | No requirement |

For example, adjustment 4 is made during 15 minutes which is the total of 10 minutes taken for movement from the I/F 100 to the I/O chamber 200, and five minutes taken for movement from the I/O chamber 200 to the soaking chamber 350.

Adjustment 1 and adjustment 3 are made during 40 minutes for soaking in the soaking chamber 350. Subsequently, adjustment 2 is made by utilizing the time of movement from the soaking chamber 350 to the alignment chamber 320, and movement from the alignment chamber 320 to the W chamber 400.

Because the time taken for the movement from the soaking chamber 350 to the alignment chamber 320 is five minutes, and the time taken for the movement from the alignment chamber 320 to the W chamber 400 is five minutes, after the movement of the substrate M to the W chamber 400, there is 10 minutes standby time before adjustment 2 is completed. In this example, the time taken since the substrate M is received by the I/F 100 until all adjustments 1 to 4 are completed after transport of the substrate M to the W chamber 400 is 75 minutes.

When adjustments 1 to 4 are collectively performed as “pre-adjustment” at the time of soaking of the substrate M without considering the attribute information on adjustments 1 to 4, the pre-adjustment is started along with the start of soaking in the soaking chamber 350. Because 75 minutes (=10 minutes+20 minutes+30 minutes+15 minutes) are taken for the pre-adjustment, after completion of soaking, the substrate M needs to be in stand-by for 35 minutes in the soaking chamber 350 until the pre-adjustment is completed. In this example, the time taken since the substrate M is received from the outside of the electron beam writing apparatus by the I/F 100 (or since the substrate M is set in the I/F 100 to be in stand-by state) until the pre-adjustment (adjustments 1 to 4) are completed after transport of the substrate M to the W chamber 400 is 100 minutes.

Determining the execution timing of each adjustment work by considering the attribute information can reduce the time since the substrate M is received by the I/F 100 until the writing process is ready to be started, thus can improve the productivity.

When the time allocated to the adjustment work for a device (device included in the writing apparatus) during transport of one substrate M is shorter than the time taken for the adjustment work for the device, the adjustment work for the device is divided, and performed over the transport of the substrate M for multiple times (transport of multiple pieces of the substrate).

The control function of the adjustment work by the control device 600 may be configured by either hardware such as an electric circuit or software such as program performing these functions. When configured by software, a program that realizes at least part of functions of the control device 600 may be stored on a non-transitory recording medium 602 such as a CD-ROM and read and executed by a computer including a CPU. The recording medium 602 is not limited to a removable recording medium such as a magnetic disk or optical disk, but may be a non-removable recording medium such as a hard disk device or memory.

In the embodiment, the configuration in which a single beam is used has been described. However, the configuration in which a multi-beam is used may be adopted.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A method of adjusting charged particle beam writing apparatus, the method comprising:
transporting a substrate before writing received via an interface from an outside to a writing chamber and placing the substrate on a stage; irradiating the substrate on the stage with a charged particle beam to write a pattern; and transporting the substrate after writing from the writing chamber to the outside via the interface,
wherein at least part of adjustment work for devices in the charged particle beam writing apparatus is performed during transport of the substrate between the interface and the writing chamber.

2. The method of adjusting charged particle beam writing apparatus according to claim 1,
wherein a plurality of types of adjustment work are performed during transport of the substrate.

3. The method of adjusting charged particle beam writing apparatus according to claim 1,
wherein execution timing of the adjustment work is determined based on attribute information that defines whether the adjustment work can be performed during transport of the substrate and a position where the substrate is located when the adjustment work is performed.

4. The method of adjusting charged particle beam writing apparatus according to claim 1,
wherein the devices include a plurality of DAC (digital analog converter) amplifiers connected to a deflector that deflects the charged particle beam.

5. The method of adjusting charged particle beam writing apparatus according to claim 1,
wherein adjustment work for the devices included in the charged particle beam writing apparatus is divided into multiple-times substrate transports and performed, where one-time substrate transport refers to transport of a substrate since the substrate is received by the interface until the substrate is placed on the stage.

6. A charged particle beam writing apparatus comprising:
an interface configured to receive a substrate from an outside and transport the substrate to the outside;
a writing chamber which is provided with a stage for placing the substrate, and in which the substrate placed on the stage is irradiated with a charged particle beam to write a pattern; and
a transporter configured to transport the substrate between the interface and the writing chamber,
wherein at least part of adjustment work for component devices is performed during transport of the substrate between the interface and the writing chamber.

7. A computer-readable recording medium storing a program causing a computer of a charged particle beam writing apparatus to execute a process comprising:
transporting a substrate before writing received from an outside via an interface of the charged particle beam writing apparatus to a writing chamber, and placing the substrate on a stage;
irradiating the substrate on the stage with a charged particle beam to write a pattern;
transporting the substrate after writing from the writing chamber to the outside via the interface; and
performing at least part of adjustment work for devices in the charged particle beam writing apparatus during transport of the substrate between the interface and the writing chamber.
